(19) United States
(12) Patent Application Publication
(10) Pub. No.: US 2025/0242458 A1
(43) Pub. Date: Jul. 31, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Yutaka MOMIYAMA, Fukuoka (JP); Ikuo ITAKURA, Fukuoka (JP); Hitoshi SASAKI, Fukuoka (JP)

(21) Appl. No.: 19/035,492

(22) Filed: Jan. 23, 2025

(30) Foreign Application Priority Data
Jan. 25, 2024 (JP) 2024-009229

(51) Int. Cl. B23Q 3/15; H02N 13/00

(52) U.S. Cl. CPC B23Q 3/15; H02N 13/00

(57) ABSTRACT

An electrostatic chuck includes a dielectric substrate and a base plate joined to the dielectric substrate. The base plate includes a first part that is a part on the dielectric substrate side, and a second part which is a part adjacent to the first part from an opposite side of the dielectric substrate and which has an outer shape larger than an outer shape of the first part in top view. The base plate is constituted by joining a plurality of members to each other, and a joint boundary B1 closest to the dielectric substrate is located in the second part.

### CROSS-REFERENCE TO RELATED APPLICATION

This application is based upon and claims the benefit of priority from Japanese Patent Application No. 2024-009229 filed on Jan. 25, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

As described in Japanese Patent Laid-Open No. 2015-35447, a coolant flow path or the like through which a coolant flows is formed inside the base plate. To facilitate formation of the coolant flow path or the like, the base plate generally has a configuration in which a plurality of members are joined to each other. For example, when a groove is formed in a front surface of one member and another member is joined so as to cover the front surface, it is possible to easily form a flow path along the groove inside the base plate.

### SUMMARY

In addition to the above-mentioned coolant flow path, a supply flow path for guiding a gas towards a placement surface of the dielectric substrate is also formed in the base plate. A porous member for avoiding discharge may also be arranged inside the supply flow path. In this manner, an inner structure in a part in the vicinity of the dielectric substrate in the base plate is relatively complex in many cases.

As described above, the base plate generally has a configuration in which a plurality of members are mutually joined. To realize the complex inner structure as described above, there is a room for a further improvement in an electrostatic chuck in related art with regard to where a joint boundary between the members in the base plate is to be positioned.

The present invention has been made in view of such an issue and is aimed to provide an electrostatic chuck in which a complex inner structure of a base plate can be easily provided.

To address the above-mentioned issue, an electrostatic chuck according to an aspect of the present invention includes a dielectric substrate including a placement surface on which an object to be attracted is placed, and a base plate joined to the dielectric substrate. The base plate includes a first part that is a part on the dielectric substrate side, and a second part which is a part adjacent to the first part from an opposite side of the dielectric substrate and which has an outer shape larger than an outer shape of the first part when viewed from a direction perpendicular to the placement surface. The base plate is constituted by joining a plurality of members to each other, and a joint boundary closest to the dielectric substrate is located in the second part.

In the electrostatic chuck with the above-mentioned configuration, the base plate is constituted by joining the plurality of members to each other, and the joint boundary closest to the dielectric substrate is located in the second part instead of the first part. As compared with a case where the joint boundary is located in the first part, since the member closest to the dielectric substrate is thickened, for example, it becomes possible to facilitate an operation of arranging a porous member in a supply flow path for a gas or the like. According to this, it is possible to easily provide a complex inner structure in the base plate.

According to the aspect of the present invention, it is possible to provide the electrostatic chuck in which the complex inner structure of the base plate can be easily provided.

### BRIEF DESCRIPTION OF THE DRAWINGS

FIG. 1 is a cross sectional view schematically illustrating a configuration of an electrostatic chuck according to the present embodiment; and

FIG. 2 schematically illustrates a configuration of a distribution flow path and the like inside a base plate.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

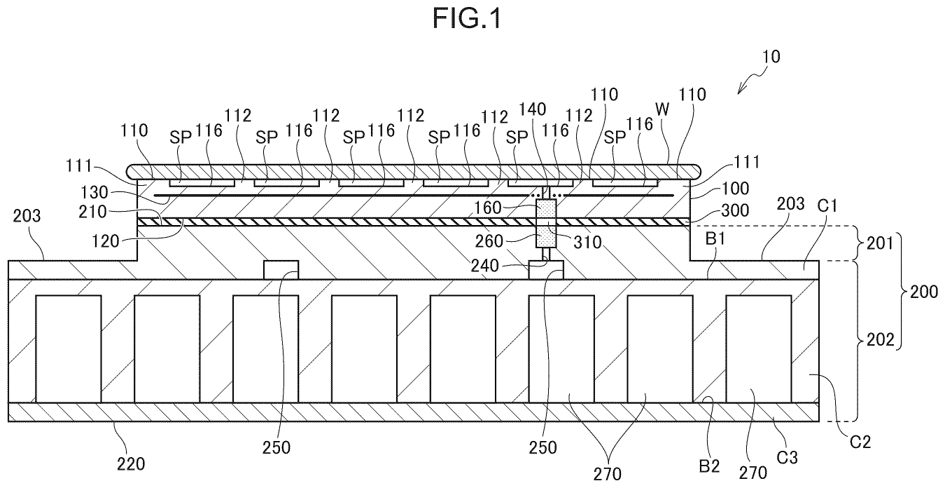

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus. A diameter of the dielectric substrate 100 is, for example, 290 to 300 mm. A thickness of the dielectric substrate 100 is, for example, 0.5 to 3.0 mm.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various configurations in related art can be adopted. The single attraction electrode 130 may be provided as so-called a “monopolar” electrode as in the present embodiment, but may also include two attraction electrodes as so-called “bipolar” electrodes. A depth of a position where the attraction electrode 130 is arranged, that is, a distance from a bottom 116 which will be described below to the attraction electrode 130 is, for example, 0.1 to 0.5 mm.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a supply flow path 140 which will be described below. When the helium gas is present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A distal end (upper end in FIG. 1) of the seal ring 111 serves as a part of the surface 110 and abuts against the wafer W. It can be mentioned that the distal end of the seal ring 111 is an outermost circumferential part of the surface 110 serving as the placement surface.

It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniform.

A part denoted by the reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A distal end of each of the dots 112 becomes a part of the surface 110 and abuts against the wafer W. By providing the plurality of thus configured dots 112, warping of the wafer W is reduced.

A supply flow path 140 is formed in the dielectric substrate 100. The supply flow path 140 is a through hole formed so as to extend in the direction perpendicular to the surface 110 serving as the placement surface. An end on the surface 110 side of the supply flow path 140 is connected to the space SP. The supply flow path 140 is a part of a flow path for supplying a helium gas towards the space SP. The supply flow path 140 includes a plurality of supply flow paths 140 which are formed in the dielectric substrate 100, but FIG. 1 illustrates only one of the supply flow paths 140.

As illustrated in FIG. 1, a part on the surface 120 side of the supply flow path 140 has an expanded diameter as compared with that of a part on the surface 110 side and includes a porous member 160 arranged therein. The porous member 160 is a porous body formed of, for example, alumina, and its entirety is breathable. By arranging the porous member 160 as described above inside the supply flow path 140, while a flow of the helium gas in the porous member 160 is secured, an occurrence of dielectric breakdown in a path through the supply flow path 140 can be reduced.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a “surface to be joined” which is joined to the dielectric substrate 100 via the joining layer 300.

The joining layer 300 is a layer provided between the dielectric substrate 100 and the base plate 200 to join those components. The joining layer 300 is provided by causing an adhesive made of an insulating material to be cured. According to the present embodiment, a silicone adhesive may be used as the above-described adhesive. It is noted however that the joining layer 300 may be provided by causing an adhesive made of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal splaying can be used. When the surface of the base plate 200 is covered by the insulating film, it is possible to increase a withstand voltage of the base plate 200.

The base plate 200 includes a first part 201 and a second part 202. The first part 201 is a part on the dielectric substrate 100 side (an upper part in FIG. 1) of the base plate 200 and is a substantially cylindrical part which directly supports the dielectric substrate 100 from below. A diameter of the first part 201, that is, a diameter of the surface 210 may be the same as the diameter of the dielectric substrate 100 but may be slightly smaller than the diameter of the dielectric substrate 100. The diameter of the first part 201 is, for example, 290 to 300 mm. A thickness of the first part 201, that is, an amount of protrusion of the first part 201 which faces upwards in FIG. 1 (amount of protrusion from the second part 202) is, for example, 3 to 15 mm.

The second part 202 is a part adjacent to the first part 201 from an opposite side (lower side in FIG. 1) of the dielectric substrate 100 in the base plate 200. According to the present embodiment, a whole of a part except for the first part 201 of the base plate 200 serves as the second part 202. A shape of the second part 202 is an approximately cylindrical shape, and a central axis of the second part 202 matches a central axis of the first part 201. A thickness of the second part 202 is, for example, 25 to 40 mm. A diameter of the second part 202 is larger than a diameter of the first part 201. An amount of protrusion from the lateral surface of the first part 201 of the second part 202 (that is, an amount of protrusion in the radial direction) is, for example, 20 to 30 mm. Therefore, an outer shape of the first part 201 in top view is smaller than an outer shape of the second part 202 in top view.

When a process on the wafer W is to be performed in the semiconductor manufacturing apparatus, a focus ring which is not illustrated in the drawing is installed on an upper surface 203 of the second part 202. The focus ring is an annular and plate-like member made of an insulating material such as quartz, for example, and is installed for a purpose of regulating a distribution of plasma during the process. A state is established in which almost the whole of the dielectric substrate 100 and the first part 201 is surrounded by the focus ring from an outer circumferential side.

A coolant flow path 270 through which a coolant flows is formed inside the base plate 200. When the process such as etching is performed in the semiconductor manufacturing apparatus, the coolant is supplied from the outside to the coolant flow path 270, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant.

As illustrated in FIG. 1, a coolant flow path 270 is routed in not only a part immediately below the wafer W of the base plate 200 but also an outer part relative to the part immediately below the wafer W. A focus ring or the like which is not illustrated in the drawing immediately above the upper surface 203 is cooled down by the coolant flowing through the outer part, and the outer circumferential part of the wafer W is also cooled down via these.

According to the present embodiment, the diameter of the second part 202 is relatively large. By setting the second part 202 to be large and forming the coolant flow path 270 across almost the whole of the second part 202 to cause the coolant to circulate therethrough, it becomes possible to reduce the temperature increase in the outer circumferential part of the wafer W.

A supply flow path 240 is formed in the base plate 200. The supply flow path 240 is a hole formed so as to extend in a direction perpendicular to the surface 110 serving as the placement surface. The supply flow path 240 extends from the surface 210 up to a distribution flow path 250 which will be described below. The supply flow path 240 is formed in each of positions overlapped with the supply flow path 140 in top view and communicably connected to the supply flow path 140 via a through hole 310 provided in the joining layer 300. The supply flow path 240 serves as a part of the flow path for supplying the helium gas towards the space SP on the placement surface side together with the supply flow path 140 of the dielectric substrate 100.

As illustrated in FIG. 1, the part on the surface 210 side of the supply flow path 240 has an expanded diameter as compared with that of the part on the distribution flow path 250 side and includes a porous member 260 arranged inside. The porous member 260 is a porous body formed of, for example, alumina, and its entirety is breathable. By arranging the porous member 260 as described above inside the supply flow path 240, while a flow of the helium gas in the supply flow path 240 is secured, an occurrence of dielectric breakdown in a path through the supply flow path 240 can be reduced.

The distribution flow path 250 is formed inside the base plate 200. The distribution flow path 250 is a flow path for distributing the helium gas to each of the supply flow paths 240. The distribution flow path 250 is routed in parallel to the surface 210 and connected to a lower end of each of the supply flow paths 240.

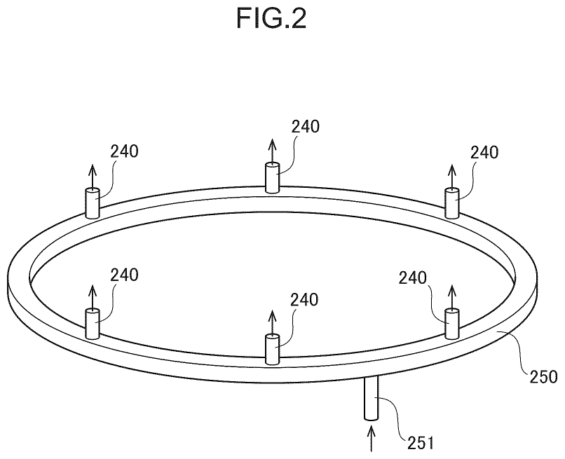

FIG. 2 schematically depicts a configuration of the distribution flow path 250 inside the base plate 200, the supply flow path 240 connected to the base plate 200, and the like. An arrow in FIG. 2 represents a flow of the helium gas. A part denoted by a reference sign “251” in FIG. 2 represents a flow path for the helium gas which is formed in the base plate 200 such that the helium gas supplied from the outside is to be guided to the distribution flow path 250. The flow path will also be hereinafter referred to as a “flow path 251”. One end of the flow path 251 is connected to the distribution flow path 250. The other end of the flow path 251 is opened in the surface 220 on the opposite side to the surface 210 in the base plate 200.

As illustrated in FIG. 2, the plurality of supply flow paths 240 are arranged so as to be aligned in a circular pattern in top view according to the present embodiment. The distribution flow path 250 is routed in a circular pattern so as to pass through a position immediately below each of the supply flow paths 240 in top view. The lower end of each of the supply flow paths 240 is connected to the distribution flow path 250. For this reason, the helium gas supplied from the outside passes through the flow path 251 to be supplied to the distribution flow path 250 and distributed from the distribution flow path 250 to each of the supply flow paths 240. Thereafter, the helium gas is supplied from each of the supply flow paths 240 through the supply flow path 140 immediately above the supply flow path 240 to the space SP. By forming the distribution flow path 250 inside the base plate 200, the number of parts where the helium gas is supplied from the outside (that is, the flow paths 251) can be reduced.

In this manner, the coolant flow path 270, the distribution flow path 250, the supply flow path 240, and the like are formed inside the base plate 200, and the base plate 200 has the relatively complex inner structure. Moreover, since the porous member 260 is arranged in each of the supply flow paths 240, the inner structure on the dielectric substrate 100 side of the base plate 200 becomes a further complex structure.

To facilitate the formation of the coolant flow path 270 and the like, the base plate 200 of the present embodiment is formed by joining a plurality of members to each other. Specifically, the base plate 200 is formed by mutually joining three members including a first member C1, a second member C2, and a third member C3 to be integrated. Each member is joined by welding, but for example, each member may be joined by a method such as brazing or fastening and fixing. The number of members constituting the base plate 200 may be four or more, or may be two.

The first member C1, the second member C2, and the third member C3 are aligned in the stated order along the direction perpendicular to the surface 110 serving as the placement surface. The first member C1 is a part closest to the dielectric substrate 100 among the members constituting the base plate 200. The surface 210 described above is a part of the first member C1. The third member C3 is a part on an opposite side of the dielectric substrate 100 among the members constituting the base plate 200. The surface 220 described above is a part of the third member C3. The second member C2 is a member located between the first member C1 and the third member C3.

A joint boundary B1 between the first member C1 and the second member C2 is parallel to the surface 110 and the surface 210. A joint boundary B2 between the second member C2 and the third member C3 is also parallel to the surface 110 and the surface 210.

The joint boundary B1 is a joint boundary closest to the dielectric substrate 100 among a plurality of joint boundaries. The first member C1 is a member located on the dielectric substrate 100 side relative to the joint boundary B1. The second member C2 is a member joined to the first member C1 while the joint boundary B1 is sandwiched.

As illustrated in FIG. 1, both the distribution flow path 250 and the supply flow path 240 according to the present embodiment are entirely formed in the first member C1. Before each member is joined, the distribution flow path 250 is an annular groove which has been formed in advance along a front surface serving as the joint boundary B1 in the first member C1. In this manner, by forming the groove in the front surface of the first member C1 in advance and joining the second member C2 so as to cover the front surface, the distribution flow path 250 along the groove can be easily formed inside the base plate 200. It is noted that the groove serving as the distribution flow path 250 may be formed in a front surface serving as the joint boundary B1 in the second member C2 instead of the front surface of the first member C1.

As illustrated in FIG. 1, the coolant flow path 270 according to the present embodiment is entirely formed in the second member C2. Before each member is joined, the coolant flow path 270 is a groove which has been formed in advance along a front surface serving as the joint boundary B2 in the second member C2. In this manner, by forming the groove in the front surface of the second member C2 in advance and joining the third member C3 so as to cover the front surface, the coolant flow path 270 along the groove can be easily formed inside the base plate 200. It is noted that the groove serving as the coolant flow path 270 may be formed in a front surface serving as the joint boundary B1 in the second member C2.

If the joint boundary B1 closest to the dielectric substrate 100 is located in the first part 201, the first member C1 becomes thinner as compared with the present embodiment. As a result, a need arises to arrange each of the porous members 260 so as to straddle both the first part 201 and the second part 202. For example, in a state in which the porous member 260 is inserted into each of recessed sections of the second member C2 and each of the porous members 260 protrudes from the front surface of the second member C2, the first member C1 is joined so as to cover the front surface of the second member C2. At this time, the joining is to be conducted while such an alignment is performed that each of the porous members 260 protruding from the front surface of the second member C2 is accommodated in a recessed section of the first part 201. However, the porous member 260 is a very small and fragile member, and the number of porous members 260 is high. Therefore, it is very difficult to perform the operation such as the above-mentioned alignment without scratching the porous member 260.

In view of the above, the base plate 200 of the present embodiment adopts the configuration in which the joint boundary B1 closest to the dielectric substrate 100 is located in the second part 202 instead of the first part 201. In other words, a configuration is adopted in which the first part 201 and a part of the second part 202 become an integrated member (the first member C1) without the intermediation of a joint boundary. In such a configuration, as compared with a case where the joint boundary B1 is located in the first part 201, the first member C1 closest to the dielectric substrate 100 is thickened. Thus, as in the present embodiment, the porous member 260 can be entirely arranged inside the first part 201. Since there is no possibility that the porous member 260 is to be scratched when the first member C1 and the second member C2 are joined to each other, it is possible to facilitate the operation such as the above-mentioned alignment or joining. According to this, the complex inner structure of the base plate 200 can be easily provided.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed; and
a base plate joined to the dielectric substrate, wherein
the base plate includes
a first part that is a part on a dielectric substrate side, and
a second part which is a part adjacent to the first part from an opposite side of the dielectric substrate and which has an outer shape larger than an outer shape of the first part when viewed from a direction perpendicular to the placement surface,
the base plate is constituted by joining a plurality of members to each other, and
a joint boundary closest to the dielectric substrate is located in the second part.

2. The electrostatic chuck according to claim 1, wherein
when among the plurality of members constituting the base plate,
a member located on the dielectric substrate side relative to the joint boundary is set as a first member, and
a member joined to the first member while the joint boundary is sandwiched is set as a second member,
a supply flow path for supplying a gas towards the placement surface is formed in the first member so as to extend in the direction perpendicular to the placement surface, and a porous member is arranged inside the supply flow path.

3. The electrostatic chuck according to claim 2, wherein
the supply flow path includes a plurality of supply flow paths, and
a distribution flow path for distributing the gas to the plurality of supply flow paths is further formed in the base plate.

4. The electrostatic chuck according to claim 3, wherein
the distribution flow path is a groove formed so as to extend along the joint boundary in either the first member or the second member.
